(19) United States
(12) Patent Application Publication
(10) Pub. No.: US 2025/0118957 A1
(43) Pub. Date: Apr. 10, 2025

(54) HIGH-PRECISION CURRENT DETECTION METHOD AND CHIP MODULE THEREFOR

(71) Applicant: SHANGHAI METAPWR ELECTRONICS CO., LTD, Shanghai (CN)

(72) Inventor: Jianhong ZENG, Shanghai (CN)

(73) Assignee: SHANGHAI METAPWR ELECTRONICS CO., LTD, Shanghai (CN)

(21) Appl. No.: 18/957,879

(22) Filed: Nov. 25, 2024

Related U.S. Application Data
(63) Continuation of application No. PCT/CN2023/095904, filed on May 23, 2023.

(30) Foreign Application Priority Data
May 24, 2022 (CN) 202210571509.6

(51) Int. Cl. H02H 7/18; G01R 31/3842; H02H 1/00

(52) U.S. Cl. CPC H02H 7/18; G01R 31/3842; H02H 1/0007

(57) ABSTRACT

A high-precision current detection method for current detection in a current loop with at least two protection switches. The method includes: arranging a sampling bridge arm which are connected in parallel on at least one protection switch. The sampling bridge arm comprises at least one current sampling switch and at least one signal processing unit which are connected in series, the current sampling switches are at least two connected in parallel and/or at least two corresponding protection switches are connected in parallel; the current sampling switch obtains a current sampling signal Is by using a mirror current method; and the signal processing unit generates a protection switch current signal Ip according to the current sampling signal Is.

### CROSS-REFERENCE TO RELATED APPLICATIONS

This application is a continuation of international application of PCT patent application PCT/CN2023/095904, filed on May 23, 2023, which claims the priority benefit of China application no. 202210571509.6 filed on May 24, 2022. The entirety of the above-mentioned patent application is hereby incorporated by reference herein and made a part of this specification.

### Technical Field

The invention relates to the field of semiconductor technology, and in particular relates to a high-precision current detection method and chip module therefor.

### Description of Related Art

For a lithium battery, the ideal working range of the lithium battery is limited greatly and is not wide, and a series of potential safety hazards can be brought to the lithium battery in the over-voltage (over-charging), over-current and over-temperature states. Therefore, the lithium battery must be managed in the application process, especially in the application scene of the power battery. In order to better and safely play the characteristics of the battery, parameters such as voltage, current and temperature of the battery generally need to be accurately measured, and the state of the battery is calculated and estimated through a series of complex algorithms, so that high requirements are provided for the sampling precision. Voltage and temperature sampling in the prior art can be obtained and good through high-precision ADC, but for current sampling, one scheme in the prior art is to read the voltage at the two ends of the sampling resistor to reflect the current (I=Vs/Rs). Since the sampling resistor is connected in series in the current path, in order to reduce the loss caused by the sampling resistor, the sampling resistor usually cannot be selected to be too large, so that the sampling signal is very small when a small current is generated, and as shown in FIG. 1B, the sampling error is large. In addition, the resistance of the sampling resistor changes along with the temperature, so that sampling errors at different temperatures are caused. The electric quantity meter is calculated by integrating the current, and it is assumed that the electric quantity is seriously inaccurate due to the fact that the long-term small current is not collected or inaccurate in sampling.

In order to solve the above problems, another scheme in the prior art is a current sampling method of a mirror current source. As shown in FIG. 1A, the protection switches S1 and S2 are integrated on one chip, and the current sampling switch S21 and the signal processing unit are integrated on the S1 or S2. The area Ms of the sampling switch S21 is far smaller than the area of S2, for example, the area Mp of S2 is Q times of the area Ms of the sampling switch S21, Q is a sampling proportion parameter, for example, Q is equal to 5000, the conduction resistance RS of the corresponding sampling switch is 5000 times of that of the S2 conduction resistor RP, as shown in the following formula:

$$Q = Rs / Rp ;$$

$$Ip = Q \cdot Is .$$

Because the current sampling switch and the protection switch are integrated in the same chip, and the same process is adopted, the performance of the current sampling switch S21 and the performance of the protection switch S2 are consistent, and the sampling signal is not affected by factors such as temperature. Because the protection switch S2 is a device which must exist in the battery protection circuit, current is sampled in a mirror current source mode of the integrated current sampling switch, and extra sampling loss cannot be brought.

The signal noise of the current sampling method of the mirror current source mainly comes from the residual voltage difference of the input end of the arithmetic unit in the signal processing unit, and the sampling proportion parameter Q needs to consider the voltage withstanding performance of the device when the chip is manufactured, so that the setting range of the sampling proportion parameter Q is limited, so that for a small protection switch current signal Ip, the current sampling signal Is is correspondingly small, and the signal-to-noise ratio is low.

Therefore, how to improve the sampling precision while saving the cost and improve the signal-to-noise ratio is an urgent problem to be solved.

### SUMMARY

In view of the above, one of the objectives of the present application is to provide a high-precision current detection method used for current detection in a current loop with at least one protection switch, and is characterized by comprising the following steps:
sampling bridge arms are arranged on at least one protection switch in parallel; the sampling bridge arm comprises at least one current sampling switch and at least one signal processing unit which are connected in series; the number of the current sampling switches is at least two, and/or the corresponding protection switches are at least two in parallel; the signal processing unit is used for processing a current sampling signal Is and adjusting the switching states of the current sampling switch and/or the protection switch;
the current sampling switch obtains a current sampling signal Is by using a mirror current source method;
presetting at least one sampling proportion parameter adjustment threshold;
sampling a first current loop parameter, the first current loop parameter being used for representing a high and low state of the load of a current loop; Determining a magnitude relationship between the first current loop parameter and the sampling proportional parameter adjustment threshold, and adjusting a switching state of the current sampling switch and/or the protection switch according to a determination result;
calculating a current signal Ip according to the current sampling signal Is, and calculating a protection switch current signal Ip by means of a formula (1.1) and a formula (1.2):

$$Q = Rs / Rp ; \qquad ( 1.1 )$$

$$Ip = Q \cdot Is ; \qquad ( 1.2 )$$

wherein Rp is the total equivalent resistance of the protection switch in on state, Rs is the total equivalent resistance of the sampling switch in on state, and Q is the sampling proportion parameter.

Preferably, the high-precision current detection method, characterized in that,
the sampling proportion parameter Q is stepped down along with the increase of the load of the current loop by adjusting the switching state of the current sampling switch and/or the protection switch.

Preferably, the high-precision current detection method, characterized in that,
sampling bridge arms are respectively arranged on at least two parallel protection switches, and signal output ends of the sampling bridge arms are electrically connected with each other.

Preferably, the high-precision current detection method, characterized in that,
sampling bridge arms are arranged on the at least two parallel protection switches, the sampling bridge arm comprises a current sampling switch corresponding to the protection switch and at least one signal processing unit, one end of the current sampling switch is electrically connected with one input end of the signal processing unit, and the at least two current sampling switches are electrically connected with the same signal processing unit.

Preferably, the high-precision current detection method, wherein the protection switch and the corresponding current sampling switch are integrated in the same chip.

Preferably, a chip module adopting the high-precision current detection method, comprising at least one protection switch, at least one current sampling switch and at least one signal processing unit;
the current sampling switch is electrically connected to one input end of the signal processing unit;
two ends of the at least one protection switch are respectively electrically connected to the other input end of the signal processing unit and the current sampling switch.

Preferably, the chip module further comprises: a metering unit, the metering unit being used for receiving a voltage sampling signal Vs converted by a current sampling signal Is, and converting the sampling voltage signal Vs into a metering value of a protection switch current signal Ip according to the sampling proportion parameter Q;
the signal processing unit comprises an arithmetic unit, a first current loop parameter transmission port and a controller;
the arithmetic unit is used for maintaining the same voltage difference between the current sampling switch and the corresponding protection switch;
the first current loop parameter transmission port is used for receiving or outputting a first current loop parameter;
the controller is used for adjusting the turning-on and turning-off of the current sampling switch and/or the protection switch;
the controller is electrically connected to the arithmetic unit and the first current loop parameter transmission port respectively;
the metering unit is electrically connected to the controller.

Preferably, the chip module, characterized in that,
the metering unit is electrically connected with a first current loop parameter transmission port, and the first current loop parameter transmission port outputs a first current loop parameter to a metering unit;
the metering unit obtains a corresponding sampling proportion parameter Q according to the first current loop parameter, and converts the sampling voltage signal Vs into a metering value for protecting the switching current signal Ip.

Preferably, the chip module, characterized in that,
the signal processing unit further comprises an auxiliary switch unit, and the auxiliary switch unit is used for adjusting the decoupling resistance value according to the first current loop parameter, so that the product of the decoupling resistance value and the sampling proportion parameter Q corresponding to the first current loop parameter is a constant value;
the controller is electrically connected to the auxiliary switch unit;
the auxiliary switch unit is electrically connected to the metering unit;
the metering unit receives a voltage sampling signal Vs obtained by multiplying the current sampling signal Is and the decoupling resistance value.

Preferably, the chip module further comprises at least one first protection switch which is not provided with a sampling bridge arm in parallel;
the first current loop parameter transmission port is electrically connected to two ends of the first protection switch, and the first current loop parameter transmission port is used for receiving a voltage difference between two ends of the first protection switch as a first current loop parameter.

Preferably, the chip module, wherein the current loop is a battery charging current loop; The first current loop parameter transmission port is electrically connected with the battery, and the first current loop parameter transmission port is used for receiving the battery voltage difference as a first current loop parameter.

Preferably, the chip module, the first protection switch, the protection switch and the sampling bridge arm are correspondingly integrated in the same sampling chip.

Preferably, the chip module, at least two sampling chips are arranged, at least two sampling chips are connected in parallel, and the metering unit receives a sampling voltage signal Vs of each sampling chip.

Preferably, the chip module further comprises a mainboard, the sampling chip is arranged on the upper surface of the mainboard or embedded in the mainboard, the metering unit is arranged on the upper surface of the mainboard or embedded in the mainboard, a power electrode is arranged on the lower surface of the mainboard, and the mainboard is electrically connected with the sampling chip, the metering unit and the power electrode.

Preferably, a step type sampling current decoupling method of the chip module comprises the following steps:
S1, setting a corresponding number of auxiliary switch units according to the number n of protection switches, wherein the relationship between the protection switch and the auxiliary switch unit satisfies formula (2):

$${R}_{p 1} ( \frac{1}{{R}_{1}} + \frac{1}{{R}_{2}} + … + \frac{1}{\text{?}} ) \qquad ( 2 )$$

$$= ( {R}_{p 1} + {R}_{p 2} ) ( \frac{1}{{R}_{1}} + \frac{1}{{R}_{2}} + … + \frac{1}{\text{?}} )$$

$$⋮$$

$$= ( {R}_{p 1} + {R}_{p 2} + … + \text{?} ) ( \frac{1}{{R}_{1}} + \frac{1}{{R}_{2}} + … + \frac{1}{\text{?}} )$$

$$⋮$$

$$= ( {R}_{p 1} + {R}_{p 2} + … + \text{?} ) ( \frac{1}{{R}_{1}} + \frac{1}{{R}_{2}} )$$

$$= ( {R}_{p 1} + {R}_{p 2} + … + \text{?} ) ( \frac{1}{{R}_{1}} ) ;$$

$$\text{?} \text{indicates text missing or illegible when filed}$$

wherein: Rp1, Rp2 . . . Rpn is total equivalent resistance of the first, the second and the nth protection switches. R1, R2 . . . Rn is the sampling resistance values of the first, the second and the nth auxiliary switch units, j being an integer, and 1<j<n−1;
presetting (n−1) threshold values form the first threshold value to the (n−1)th threshold value which are from small to large;
S2: acquiring the first current loop parameter, and determining a magnitude relationship between the first current loop parameter and the first threshold to the (n−1)th threshold;
S3, if the first current loop parameter is lower than the first threshold, turning-on the first protection switch and all the auxiliary switch units;
if the first current loop parameter is higher than the (j−1)th threshold value and is lower than the jth threshold value, turning-on the first to the jth protection switches and the first to (n−j+1)th auxiliary switch units, wherein j is an integer, and 1<j<n−1;
if the first current loop parameter is higher than the (n−1)th threshold, turning on all the protection switches and the first auxiliary switch unit;
S4: taking the total equivalent resistance of the turning-on auxiliary switch unit as a decoupling resistance value, and outputting the voltage value of the two ends of the auxiliary switch unit as a sampling voltage signal Vs.

A high-precision current detection unit is used for current detection in a current loop with at least one protection switch, comprising at least two protection switches in parallel, a current sampling switch, a signal processing unit;
the first end of the current sampling switch is electrically connected with the first end of the protection switch; the first input end of the signal processing unit is electrically connected with the second end of the current sampling switch; the signal processing unit is used for processing a current sampling signal Is and adjusting the switching states of the current sampling switch and/or the protection switch;
a first current loop parameter is sampled by the high-precision current unit, the first current loop parameter is being used for representing a high and low state of the load of a current loop; the current sampling signal Is is used to obtain a current signal Ip by means of a formula:

$$Ip = Q \cdot Is ;$$

wherein Q is the sampling proportion parameter, and the sampling proportion parameter Q is a ratio of the total equivalent resistance of the conduction sampling switch and the total equivalent resistance of the conduction protection switch.

Preferably, the high-precision current detection unit, characterized in that, the sampling proportion parameter Q is stepped down along with the increase of the load of the current loop by adjusting the switching state of the current sampling switch and/or the protection switch.

Preferably, the high-precision current detection unit, characterized in that, the current sampling switch obtains a current sampling signal Is by using a mirror current source method.

Preferably, the high-precision current detection unit, characterized in that, presetting at least one sampling proportion parameter adjustment threshold; determining a magnitude relationship between the first current loop parameter and the sampling proportional parameter adjustment threshold, and adjusting a switching state of the current sampling switch and/or the protection switch according to a determination result.

Preferably, the high-precision current detection unit, characterized in that, wherein the protection switch and the corresponding current sampling switch are integrated in the same chip.

Preferably, the high-precision current detection unit, characterized in that, further comprising a first protection switch, the first protection switch is connected with the protection switch in series in the current loop.

Preferably, the high-precision current detection unit, characterized in that, wherein the first protection switch, the protection switch and the corresponding current sampling switch are integrated in the same chip.

A high-precision current detection chip module of comprising the high-precision current detection unit and a metering unit, the metering unit being used for receiving a voltage sampling signal Vs converted by a current sampling signal Is, and converting the sampling voltage signal Vs into a metering value of a protection switch current signal Ip according to the sampling proportion parameter Q;
the signal processing unit comprises an arithmetic unit, a first current loop parameter transmission port and a controller;
the arithmetic unit is used for maintaining the same voltage difference between the current sampling switch and the corresponding protection switch;
the first current loop parameter transmission port is used for receiving or outputting a first current loop parameter;
the controller is used for adjusting the turning-on and turning-off of the current sampling switch and/or the protection switch;
the controller is electrically connected to the arithmetic unit and the first current loop parameter transmission port respectively;
the metering unit is electrically connected to the controller.

Preferably, the chip module, characterized in that, the metering unit is electrically connected with a first current loop parameter transmission port, and the first current loop parameter transmission port outputs a first current loop parameter to a metering unit;
the metering unit obtains a corresponding sampling proportion parameter Q according to the first current loop parameter, and converts the sampling voltage signal Vs into a metering value for protecting the switching current signal Ip.

Preferably, the chip module, characterized in that, the signal processing unit further comprises an auxiliary switch unit, and the auxiliary switch unit is used for adjusting the decoupling resistance value according to the first current loop parameter, so that the product of the decoupling resistance value and the sampling proportion parameter Q corresponding to the first current loop parameter is a constant value;
the controller is electrically connected to the auxiliary switch unit;
the auxiliary switch unit is electrically connected to the metering unit;
the metering unit receives a voltage sampling signal Vs obtained by multiplying the current sampling signal Is and the decoupling resistance value.

Preferably, the chip module, characterized in that, wherein the current loop is a battery charging current loop; The first current loop parameter transmission port is electrically connected with the battery, and the first current loop parameter transmission port is used for receiving the battery voltage difference as a first current loop parameter.

Preferably, the chip module, setting a corresponding number of auxiliary switch units according to the number n of protection switches and (n−1) threshold values form the first threshold value to the (n−1)th threshold value which are from small to large;
determining the number of the turning-on protection switches and the turning-on auxiliary switch units according to the first current loop parameter and the first threshold to the (n−1)th threshold;
if the first current loop parameter is lower than the first threshold value, turning-on the first protection switch and all the auxiliary switch units;
if the first current loop parameter is higher than the (n−1)th threshold value, turning on all the protection switches and the first auxiliary switch unit.

Preferably, the chip module, wherein the protection switch and the corresponding current sampling switch are integrated in the same chip; further comprises a mainboard, the sampling chip is arranged on the upper surface of the mainboard or embedded in the mainboard, and the metering unit is arranged on the upper surface of the mainboard or embedded in the mainboard, a power electrode is arranged on the lower surface of the mainboard, and the mainboard is electrically connected with the sampling chip, the metering unit and the power electrode.

Preferably, the chip module, further comprising a first protection switch, the first protection switch is connected with the protection switch in series in the current loop; the first protection switch, the protection switch and the corresponding current sampling switch are integrated in the same chip; further comprises a mainboard, the sampling chip is arranged on the upper surface of the mainboard or embedded in the mainboard, and the metering unit is arranged on the upper surface of the mainboard or embedded in the mainboard, and the mainboard is electrically connected with the sampling chip, the metering unit and the power electrode.

Preferably, the chip module, further comprising at least one first protection switch, the at least one first protection switch is connected with the protection switch in series in the current loop; The first current loop parameter transmission port is electrically connected to two ends of the first protection switch, and the first current loop parameter transmission port is used for receiving a voltage difference between two ends of the first protection switch as a first current loop parameter.

A high-precision current detection integrated chip, comprising a protection switch and a current sampling switch;
the first end of the current sampling switch is electrically connected with the first end of the protection switch; the second end of the current sampling switch is electrically connected with a signal processing unit, the current sampling switch obtains a current sampling signal Is by using a mirror current source method; the signal processing unit is used for processing the current sampling signal Is and adjusting the switching states of the current sampling switch and/or the protection switch;
the number of the protection switch is one and the number of the current sampling switch is at least two, or, the number of the protection switch is at least two.

Preferably, the high-precision current detection integrated chip, further comprising a first protection switch, the first protection switch is reversely connected with the first end of the protection switch in series.

Preferably, the high-precision current detection integrated chip, the number of the current sampling switches is two; the second ends of the current sampling switches are respectively connected with the corresponding signal processing unit, or, the second ends of the current sampling switches are connected with the same signal processing unit.

The high-precision current detection chip module is used for current sampling in a current loop with the protection switch, the chip module comprises the integrated chip and the signal processing unit; further comprising a metering unit, the metering unit being used for receiving a voltage sampling signal Vs converted by a current sampling signal Is, and converting the sampling voltage signal Vs into a metering value of a protection switch current signal Ip according to a sampling proportion parameter Q; the relationship between the sampling proportion parameter Q and the current signal Ip of the protection switch is:

Q=Rs/Rp; Ip=Q·Is;
wherein Rp is the total equivalent resistance of the protection switch in on state, Rs is the total equivalent resistance of the sampling switch in on state;
the signal processing unit comprises an arithmetic unit, a first current loop parameter transmission port and a controller;
the arithmetic unit is used for maintaining the same voltage difference between the current sampling switch and the corresponding protection switch;
the first current loop parameter transmission port is used for receiving or outputting a first current loop parameter;
the controller is used for adjusting the turning-on and turning-off of the current sampling switch and/or the protection switch;
the controller is electrically connected to the arithmetic unit and the first current loop parameter transmission port respectively;
the metering unit is electrically connected to the controller.

Preferably, the chip module, the metering unit is electrically connected with a first current loop parameter transmission port, and the first current loop parameter transmission port outputs a first current loop parameter to a metering unit;
the metering unit obtains a corresponding sampling proportion parameter Q according to the first current loop parameter, and converts the sampling voltage signal Vs into a metering value for protecting the switching current signal Ip.

Preferably, the chip module, the signal processing unit further comprises an auxiliary switch unit, and the auxiliary switch unit is used for adjusting the decoupling resistance value according to the first current loop parameter, so that the product of the decoupling resistance value and the sampling proportion parameter Q corresponding to the first current loop parameter is a constant value;
the controller is electrically connected to the auxiliary switch unit;
the auxiliary switch unit is electrically connected to the metering unit;
the metering unit receives a voltage sampling signal Vs obtained by multiplying the current sampling signal Is and the decoupling resistance value.

Preferably, the chip module, wherein the current loop is a battery charging current loop; The first current loop parameter transmission port is electrically connected with the battery, and the first current loop parameter transmission port is used for receiving the battery voltage difference as a first current loop parameter.

Preferably, the chip module, setting a corresponding number of auxiliary switch units according to the number n of protection switches and (n−1) threshold values form the first threshold value to the (n−1)th threshold value which are from small to large;
determining the number of the turning-on protection switches and the turning-on auxiliary switch units according to the first current loop parameter and the first threshold to the (n−1)th threshold;
if the first current loop parameter is lower than the first threshold value, turning-on the first protection switch and all the auxiliary switch units;
if the first current loop parameter is higher than the (n−1)th threshold value, turning on all the protection switches and the first auxiliary switch unit.

Preferably, the chip module, further comprising at least one first protection switch, the at least one first protection switch is connected with the protection switch in series in the current loop; The first current loop parameter transmission port is electrically connected to two ends of the first protection switch, and the first current loop parameter transmission port is used for receiving a voltage difference between two ends of the first protection switch as a first current loop parameter.

Preferably, the chip module, further comprises a mainboard, the sampling chip is arranged on the upper surface of the mainboard or embedded in the mainboard, and the metering unit is arranged on the upper surface of the mainboard or embedded in the mainboard, and the mainboard is electrically connected with the sampling chip, the metering unit and the power electrode.

Compared with the prior art, the application has the following beneficial effects:

(1) Because the current sampling switch and the protection switch are integrated in the same chip, and the same process is adopted, the performance of the current sampling switch and the performance of the protection switch are consistent, and the sampling signal is not affected by factors such as temperature. Because the protection switch is a device which must exist in the battery protection circuit, current is sampled in a mirror current source mode of the integrated current sampling switch, and extra sampling loss cannot be brought.

(2) By adopting the high-precision current detection method disclosed by the application, the signal-to-noise ratio is further improved, the requirement for operational amplifier is also reduced, and meanwhile, the sampling precision is also improved. Under a large-current working condition, the conduction loss can be reduced under the condition that the sampling precision is met, and the system cost can be reduced.

(3) The sampling gain of the distributed current sampling scheme is different at different current levels, and the current sampling gain is changed in a step mode along with the changing current. The precision of sampling current in a small current period is obviously improved.

### BRIEF DESCRIPTION OF THE DRAWINGS

FIG. 1A is a circuit diagram of a sampling circuit in the prior art.

FIG. 1B is a schematic diagram of a sampling current in the prior art.

FIG. 2A and FIG. 2B are circuit diagrams of a high-precision current detection method and a corresponding chip integration schematic diagram of the high-precision current detection method according to an embodiment of the present application.

FIG. 3A and FIG. 3B are circuit diagrams of a high-precision current detection method and a corresponding chip integration schematic diagram of the high-precision current detection method according to another embodiment of the present application.

FIG. 4A, FIG. 4B, and FIG. 4C are circuit diagrams of a high-precision current detection method and a corresponding chip integration schematic diagram of the high-precision current detection method according to another embodiment of the present application.

FIG. 5A and FIG. 5B are a circuit diagram of a high-precision current detection method and a corresponding chip integration schematic diagram of the high-precision current detection method according to another embodiment of the present application.

FIG. 6A and FIG. 6B are a circuit diagram of a high-precision current detection method and a corresponding chip integration schematic diagram of the high-precision current detection method according to another embodiment of the present application.

FIG. 7A is a schematic diagram of a current sampling gain of a decoupling method for a stepped sampling current according to an embodiment of the present application.

FIG. 7B is a circuit diagram of a decoupling method for a stepped sampling current according to an embodiment of the present application.

FIG. 7C is a circuit diagram of a decoupling method of a step-type sampling current applied to a battery charging scene according to an embodiment of the present application.

FIG. 8A and FIG. 8B are an integrated schematic diagram of a sampling chip of a stepped sampling current decoupling method according to an embodiment of the present application.

FIG. 8C is a circuit diagram of a plurality of sampling chips of a decoupling method of a step-type sampling current connected in parallel according to an embodiment of the present application.

FIG. 9A to FIG. 9C are schematic diagrams of a circuit element of a stepped sampling current decoupling method provided on a mainboard according to an embodiment of the present application.

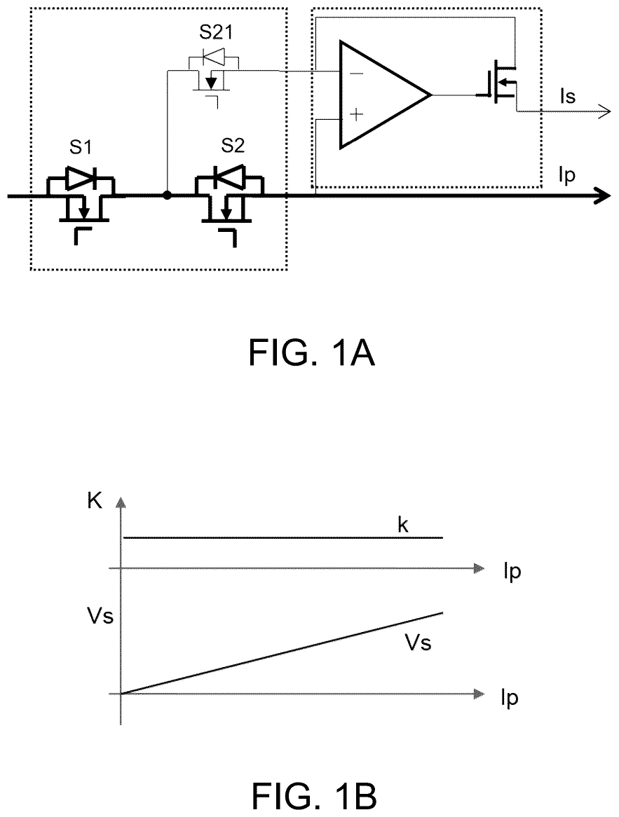

### DESCRIPTION OF THE EMBODIMENTS

The embodiment of the application discloses a high-precision current detection method. The high-precision current detection method is used for current detection in a current loop with at least one protection switch, and comprises the following steps:
a sampling bridge arm is connected with at least one current sampling switch in parallel. The sampling bridge arm comprises at least one current sampling switch and at least one signal processing unit which are connected in series; the current sampling switches are at least two, and/or the corresponding protection switches are at least two in parallel; the signal processing unit is used for processing the current sampling signal Is and enabling the sampling proportion parameter Q to descend in a stepped mode along with the rising of the current loop load by adjusting the switching states of the current sampling switch and/or the protection switch;
the current sampling switch obtains a current sampling signal Is by using a mirror current source method;
presetting at least one sampling proportion parameter adjustment threshold;
sampling a first current loop parameter, the first current loop parameter being used for representing the high and low state of t the load of the current loop;
and judging the magnitude relationship between the first current loop parameter and the sampling proportion parameter adjustment threshold value, and adjusting the on-off state of the current sampling switch and/or the protection switch according to the judgment result;
calculating a current signal Ip according to the current sampling signal Is, and calculating a protection switch current signal Ip by means of a formula (1.1) and a formula (1.2):

$$Q = Rs / Rp ; \qquad ( 1.1 )$$

$$Ip = Q \cdot Is ; \qquad ( 1.2 )$$

wherein Rp is the total equivalent resistance of the protection switch in on state, Rs is the total equivalent resistance of the sampling switch in on state, and Q is the sampling proportion parameter.

Preferably, the protection switch and the corresponding current sampling switch are integrated in the same chip.

Because the current sampling switch and the protection switch are integrated in the same chip, and the same process is adopted, the performance of the current sampling switch and the performance of the protection switch are consistent, and the sampling signal is not influenced by factors such as temperature. Because the protection switch is a device which must exist in the battery protection circuit, current is sampled in a mirror current source mode of the integrated current sampling switch, and extra sampling loss cannot be brought.

The following describes in more detail through different embodiments.

It should be noted that although the drawings of the description include the first protection switch S1, but the first protection switch S1 is not the core of the present application, the core of the present application is a protection switch S2 and a derivative thereof, a current sampling switch and a derivative thereof, and a signal processing unit, and the drawings of the description are merely exemplary.

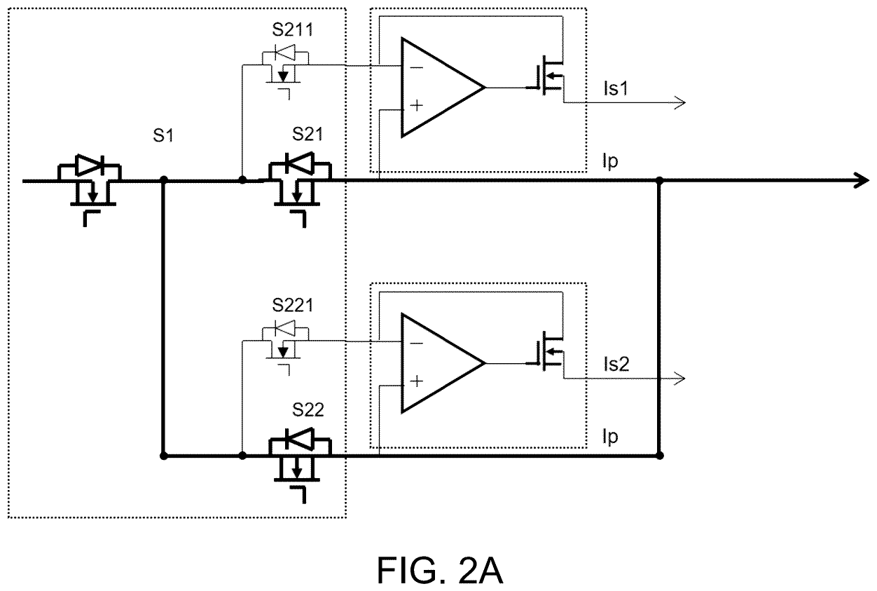

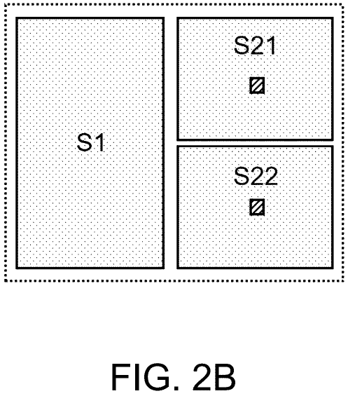

In order to improve the sampling precision of the light-load current, the application provides a distributed mirror image current sampling method. As shown in FIGS. 2A and 2B, the protection switch S2 is divided into protection switches S21 and S22 and the like, when each part of switches is integrated with the current sampling switches S211 and S221. When it is in a small current condition only the protection switch S21 is turned on, the current sampling switch S211 is used for sampling, due to the fact that only the part of the protection switch are conducted, for example, 1/2, the amplitude of a sampling signal is 2 times when all switches are switched on, the signal-to-noise ratio is further improved, the requirement for operational amplifier is also reduced, and meanwhile, the sampling precision is also improved. Under the high-current working condition, all the protection switches are turned on, and the conduction loss is reduced under the condition that the sampling precision is met.

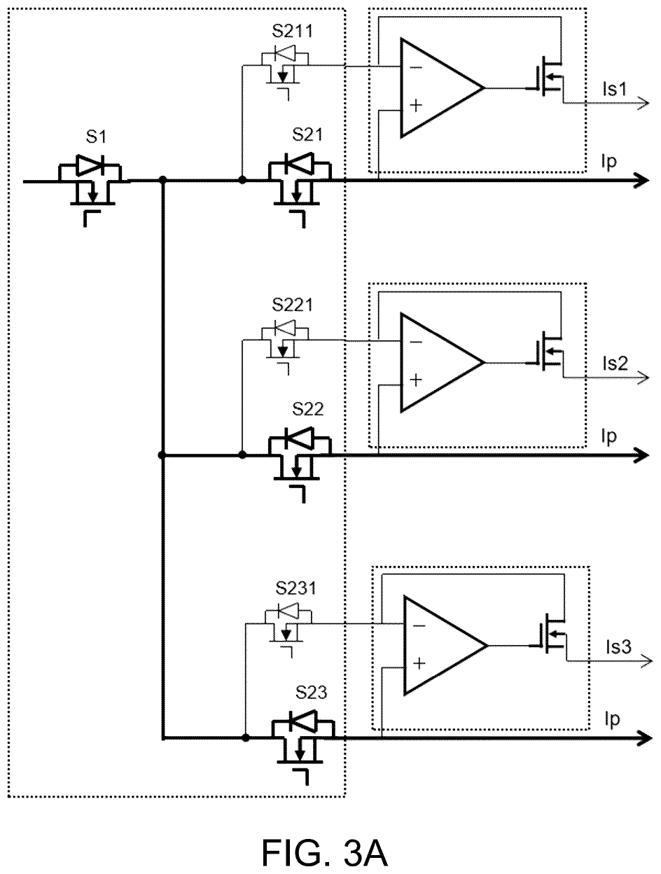

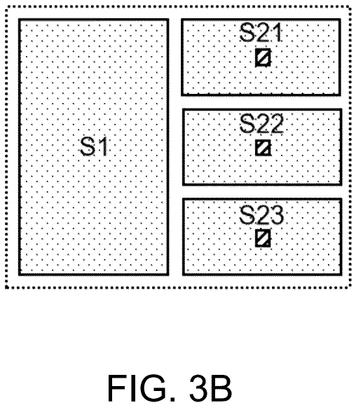

In some other embodiments, in order to further improve the light-load current sampling precision, at least two parallel protection switches are respectively provided with a sampling bridge arm, and the signal output ends of the sampling bridge arms are electrically connected to each other, as shown in FIGS. 3A and 3B, the protection switch S2 is divided into sub-switches S21, S22, S23, each part of switches is respectively integrated with the current sampling switches S211, S221 and S231. In a small current working condition, only S21 is turned on and sampling is carried out through the sampling switch S211, due to the fact that the protection switch only conducts part of switches, for example, 1/3, the amplitude of a sampling signal is 3 times when all switches are switched on, the signal-to-noise ratio is further improved, the requirement for operational amplifier is also reduced, and meanwhile, the sampling precision is also improved. In a large-current working condition, all the switches are turned on, and the conduction loss is reduced under the condition that the sampling precision is met.

In order to facilitate description, in the following embodiments, the protection switch S2 is divided into sub-switches S21, S22 and S23 as an example for description, but the application is not limited thereto, the protection switch S2 can be divided into more than or equal to two protection switches according to actual requirements, the protection switch is not limited to equalization, or the conduction resistance of each part is equal, and the size of each protection switch can be distributed according to actual requirements.

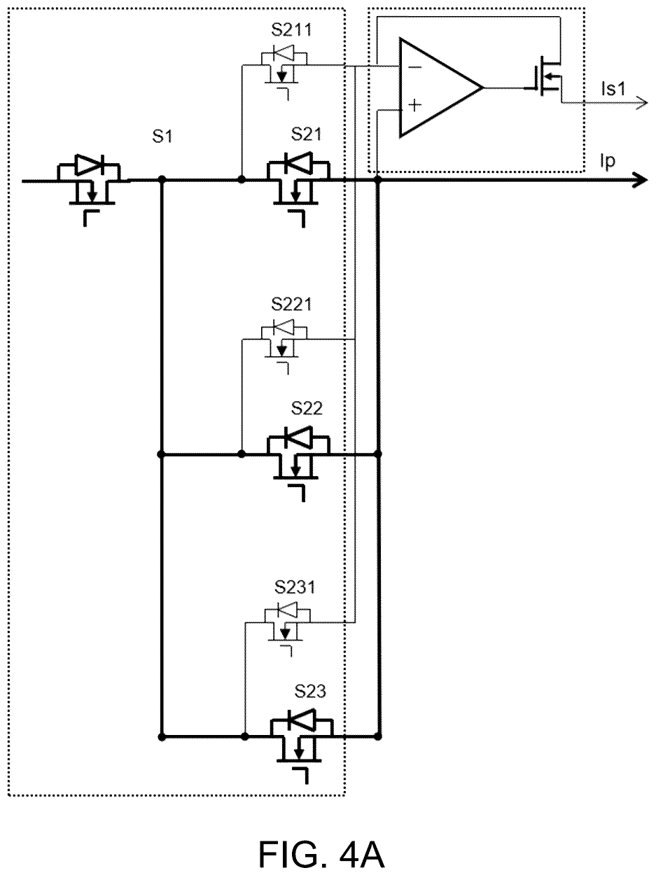

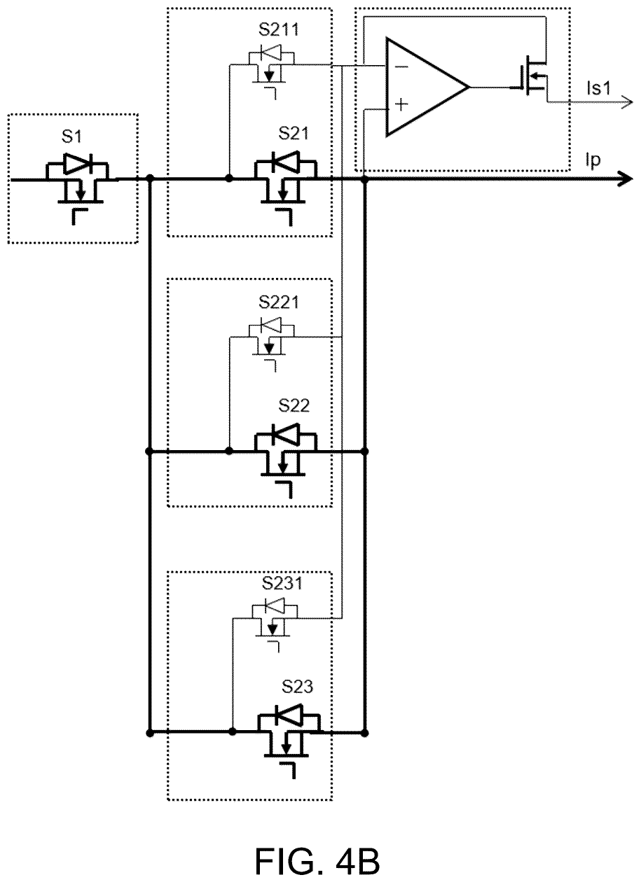

In some other embodiments, a sampling bridge arm is arranged on at least two parallel protection switches, the sampling bridge arm comprises a current sampling switch corresponding to the protection switch and at least one signal processing unit, one end of the current sampling switch is electrically connected with one input end of the signal processing unit, and the at least two current sampling switches are electrically connected with the same signal processing unit. As shown in FIG. 4A, in order to improve the sampling precision, the requirement for the operational amplifier performance is also improved, the system cost is correspondingly increased, the sampling bridge arm shares the same signal processing unit, high-precision current sampling is realized only by adopting one operational amplifier, and the output of the three current sampling switches S211, S221 and S231 is connected to the inverting input end of the operational amplifier in parallel. Only the protection switch S21 is turned on in a small current working condition, the current is sampled through the current sampling switch S211, due to the fact that only a part of the protection switch are conducted, for example, 1/3, the amplitude of a sampling signal is 3 times when all switches are switched on, the signal-to-noise ratio is further improved, the requirement for operational amplifier is also reduced, and meanwhile, the sampling precision is also improved. In a large-current working condition, all the switches are turned on, and the conduction loss is reduced under the condition that the sampling precision is met. The current sampling precision can be ensured, and the system cost can be reduced.

It should be noted that in the embodiment, the first protection switch S1 and the protection switch S2 are both integrated in the same chip, but according to actual conditions, the first protection switch S1 and the protection switch S2 can also be respectively arranged in the two chips. Furthermore, when at least two protection switches are provided with sampling bridge arms, each protection switch can also be in different chips, such as each protection switch S21, S22 and S23 shown in FIG. 4B and FIG. 4C.

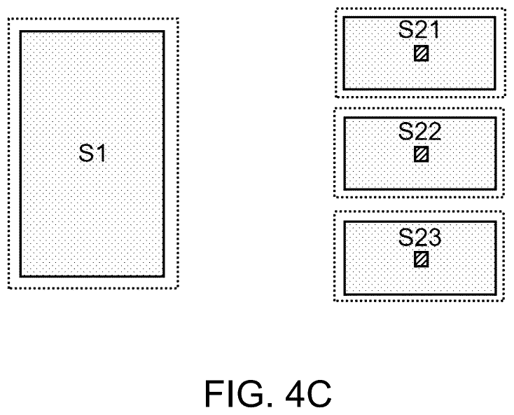

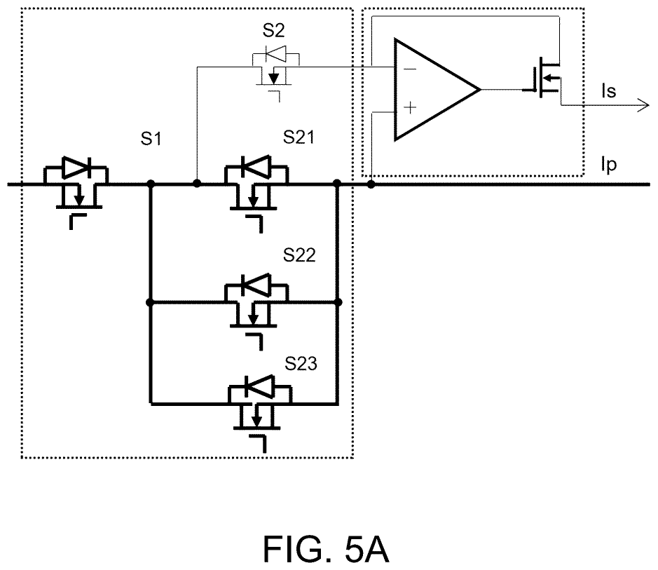

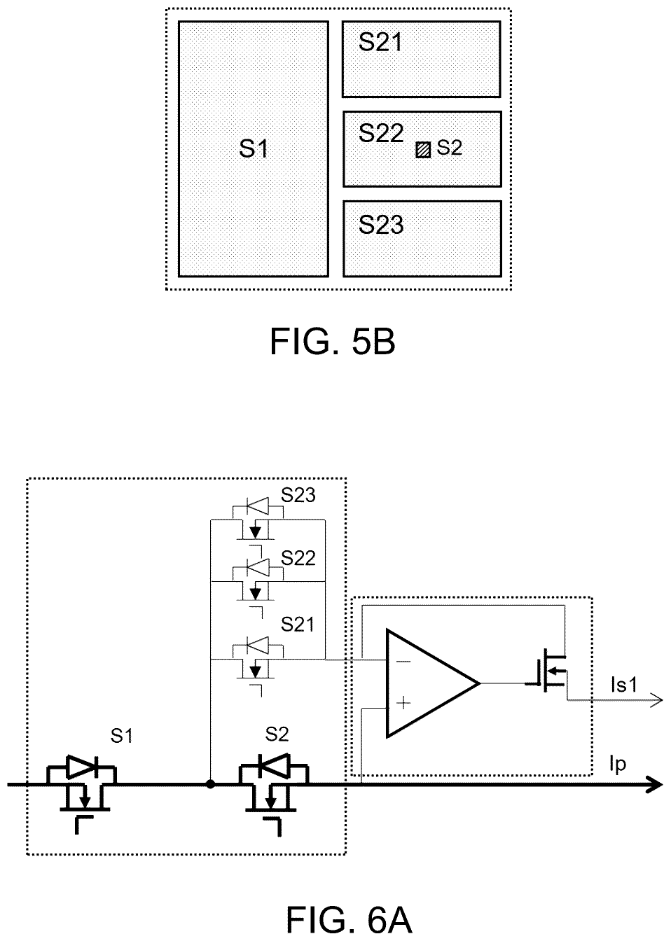

In other embodiments, sampling bridge arms are arranged on at least two parallel protection switches, and the parallel protection switches are sampled by the same current sampling switch. As shown in FIG. 5A and FIG. 5B, the current sampling switch can also be combined into one, the area waste caused by functional segmentation in the chip is reduced, the protection switch S2 is divided into protection switches S21, S22, S23 and the like, the three protection switches share a current sampling switch S2. Only S21 is turned on in a small current working condition. the current sampling switch S2 is used for sampling, because only a part of the protection switch are turned on, for example, 1/3, the amplitude of the sampling signal is 3 times when all the switches are switched on, the signal-to-noise ratio is further improved, the requirement for operational amplifier is also reduced, and meanwhile, the sampling precision is also improved. In a large-current working condition, all the switches are turned on, and the conduction loss is reduced under the condition that the sampling precision is met.

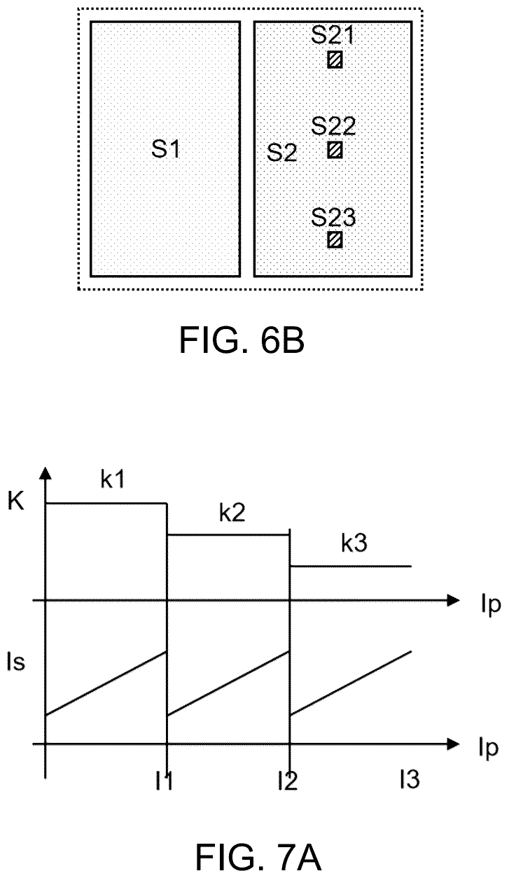

In other embodiments, the sampling bridge arm further comprises at least one current sampling switch group, and the current sampling switch group comprises at least two current sampling switches connected in parallel; at least one signal processing unit; and the signal processing unit is connected in series with the current sampling switch group. As shown in FIG. 6A and FIG. 6B, a plurality of current sampling switches and a protection switch can be arranged in parallel to adopt a distributed mirror current sampling method, and the light-load sampling precision is improved through time-sharing work of a plurality of sampling switches. For example, all the sampling switches are turned on in a small current working condition, the sampling current Is three times of the sampling current when only one sampling switch is turned on, and the requirement of improving the sampling precision under the condition of small current can also be met.

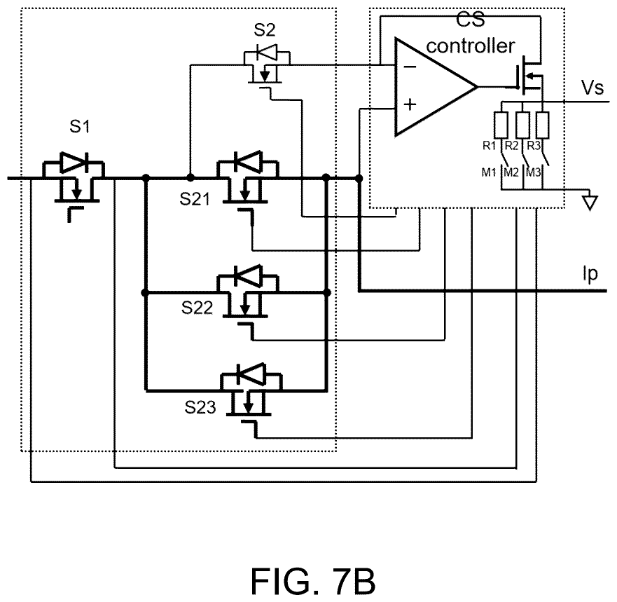

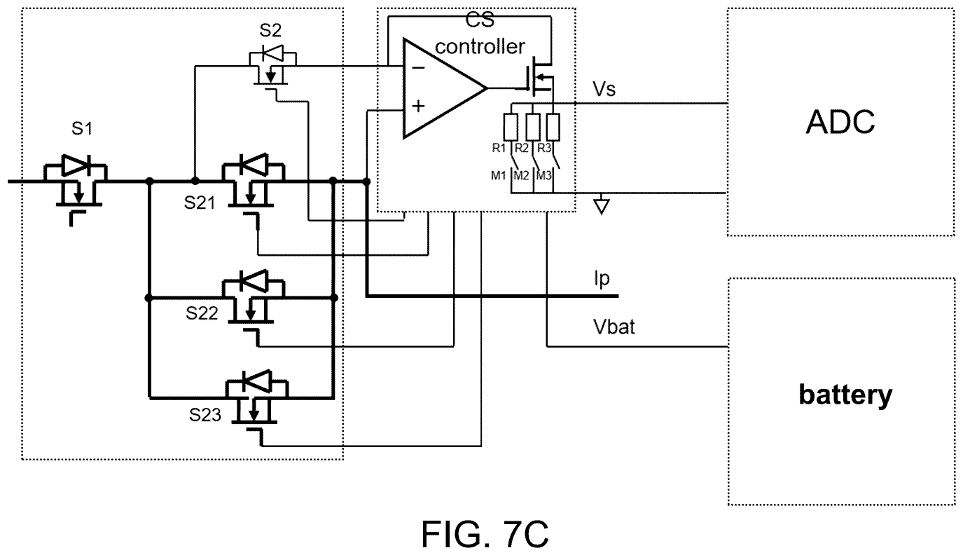

As shown in FIG. 7B, the current sampling switch is combined into one, the protection switch S2 is divided into protection switches S21, S22, S23 and the like, the three protection switches share one current sampling switch S2. Only the protection switch S21 is turned on in small current working condition, the current sampling switch S2 is used for sampling, because only a part of the protection switch are turned on, for example, 1/3, the amplitude of the sampling signal is 3 times of that of all the switches, the signal-to-noise ratio is further improved, the operational amplifier requirement is also reduced, and meanwhile, the sampling precision is also improved. In a large-current working condition, all the switches are turned on, and the conduction loss is reduced under the condition that the sampling precision is met.

It should be noted that when the current is small to a certain degree, the sampling current is inaccurate, and at the moment, the voltage drop of the protection switch S21 is kept in a relatively large state. In addition, according to actual situation requirements, a first protection switch S1 can also be provided, and only the protection switch S2 and/or the corresponding protection switches S21, S22, S23 and the like. The protection switch S2, S21, S22 and S23 are sequentially 5˜10 times of the area.

The embodiment of the application further discloses a decoupling method of the stepped sampling current. The decoupling method comprises the following steps:
S1, setting a corresponding number of auxiliary switch units according to the number n of protection switches, wherein the relationship between the protection switch and the auxiliary switch unit is shown in formula (2):

$${R}_{p 1} ( \frac{1}{{R}_{1}} + \frac{1}{{R}_{2}} + … + \frac{1}{\text{?}} ) \qquad ( 2 )$$

$$= ( {R}_{p 1} + {R}_{p 2} ) ( \frac{1}{{R}_{1}} + \frac{1}{{R}_{2}} + … + \frac{1}{\text{?}} )$$

$$⋮$$

$$= ( {R}_{p 1} + {R}_{p 2} + … + \text{?} ) ( \frac{1}{{R}_{1}} + \frac{1}{{R}_{2}} + … + \frac{1}{\text{?}} )$$

$$⋮$$

$$= ( {R}_{p 1} + {R}_{p 2} + … + \text{?} ) ( \frac{1}{{R}_{1}} + \frac{1}{{R}_{2}} )$$

$$= ( {R}_{p 1} + {R}_{p 2} + … + \text{?} ) ( \frac{1}{{R}_{1}} ) ;$$

$$\text{?} \text{indicates text missing or illegible when filed}$$

wherein: Rp1, Rp2 . . . Rpn is total equivalent resistance of the first, the second and the nth protection switches. R1, R2 . . . Rn is the sampling resistance of the first, the second and the nth auxiliary switch units, j being an integer, and 1<j<n−1;
presetting (n−1) threshold values which are from small to large and from the first threshold value to the (n−1)th threshold value;
S2: acquiring the first current loop parameter, and determining a magnitude relationship between the first current loop parameter and the first threshold value to the (n−1)th threshold value;
S3, if the first current loop parameter is lower than the first threshold, the first protection switch and all the auxiliary switch units are turned-on;
if the first current loop parameter is higher than the (j−1)th threshold value and is lower than the jth threshold value, the first to the jth protection switches and the first to (n−j+1)th auxiliary switch units, wherein j is an integer, and 1<j<n−1;
if the first current loop parameter is higher than the (n−1)th threshold, all the protection switches and the first auxiliary switch unit are turned-on;
S4: taking the total equivalent resistance of the turned-on auxiliary switch unit as a decoupling resistance value, and outputting the voltage value of the two ends of the auxiliary switch unit as a sampling voltage signal Vs.

The sampling gain of the distributed current sampling scheme is different in different current levels, as shown in FIG. 7A, the current ranges from 0 to I1, the current sampling gain is K1; the current ranges from I1 to I2, the current sampling gain is K2; the current ranges from I2 to I3, the current sampling gain is K3; and the current sampling gain changes with the changing current in a step mode. The small current sampling gain is large, the sampling current signal in the small current 0-I1 period is basically the same as the sampling current signal in the large current I2-I3 period, and compared with a traditional scheme, the precision of the sampling current in the small current period is obviously improved.

In this embodiment, N=3 is taken as an example, as shown in FIG. 7B. The signal processing unit detects the voltage drop of the first protection switch S1, controls the protection switches S21, S22 and S23 and the turn-on and turn-off of the auxiliary sampling switches M1, M2 and M3 according to the conduction voltage drop of S1, thereby obtaining a monotonic sampling voltage. For example, when the conduction voltage drop of S1 is small, for example, lower than a first threshold value, the protection switch S21 and the auxiliary switches M1, M2 and M3 are turned on at the same time, the sampling resistors R1, R2 and R3 are connected in parallel, and the sampling voltage Vs−K1×Ip×[R1R2R3/(R2R3+R1R3+R1R2)]; When the conduction voltage drop of S1 continues to increase, for example, when the conduction voltage drop is increased to be higher than the first threshold value and lower than the second threshold value, the protection switches S21 and S22 are controlled, the auxiliary switches M1 and M2 are turned on at the same time, the sampling resistors R1 and R2 are connected in parallel, and the sampling voltage Vs Vs=K2×Ip/(R1+R2). When the conduction voltage drop of S1 continues to increase, for example, when the conduction voltage drop is increased to be higher than a second threshold value, the protection switches S21, S22 and S23 are controlled, the auxiliary switch M1 is turned on at the same time, the sampling resistor is R1, the sampling voltage Vs=K3×Ip×R1. When K1=3×K3, K2=2×K3, R1=R2=R3, and the sampling voltage Vs has a relationship with the current which flows along in a linear relationship. According to the scheme, the following relationships are not limited: K1=3×K3, K2=2×K3 and R1=R2=R3, as long as the corresponding relation between K1, K2, K3, R1, R2 and R3 is ensured that the sampling voltage and the flowing current are in a linear relationship. Moreover, the voltage drop of the protection switch S1 is only used as the switching judgment logic of the current sampling switch, and the sampling precision does not need to be very high.

In some other embodiments, as shown in FIG. 7C, the battery charging is divided into two stages: a constant current pre-charging stage, a constant current charging state or a constant voltage charging state under a normal condition, and the battery voltage in the constant current pre-charging stage is very low, for example, lower than 3V. Here, a small and constant current pre-charged is used, and the current in this stage is relatively small, for example, only 100 mA; when the voltage of the battery reaches 3V, a constant-current charging mode is started, which is that the charging current is relatively large, for example, greater than 2 A; and when the voltage of the battery reaches 4.2 V, constant-voltage charging is started, then, the charging current is gradually reduced. The turn-on logic of the protection switch can also be determined by detecting the battery voltage, for example, when the battery voltage is less than 3 V, the protection switch S21, the auxiliary switches M1, M2 and M3 are turned on at the same time, the sampling resistors R1, R2 and R3 3 are connected in parallel, and the sampling voltage Vs=K1×Ip×[R1R2R3/(R2R3+R1R3+R1R2)]; when the battery voltage is greater than 4.2V, the protection switches S21 and S22 are controlled, the auxiliary switches M1 and M2 are turned on at the same time, the sampling resistors R1 and R2 are connected in parallel, and the sampling voltage Vs Vs−K2×Ip/(R1+R2); when the voltage of the battery is greater than 3V and less than 4.2 V, the main switches S21, S22 and S23 are controlled, the auxiliary switch M1 is turned on at the same time, the sampling resistor is R1, the sampling voltage Vs=K3×Ip×R1 when K1=3×K3, K2=2×K3, R1=R2=R3, the sampling voltage Vs=K3×Ip×R1, and the current which flows along with the current is in a linear relationship. According to the scheme, the following relationships are not limited: K1=3×K3, K2=2×K3, R1=R2=R3, and as long as the corresponding relation between K1, K2, K3, R1, R2 and R3 is controlled to ensure that the sampling voltage and the flowing current are in a linear relation.

According to the embodiment, the full-range sampling signal is sent to the metering unit ADC, the ADC is used for receiving the voltage sampling signal Vs converted by the current sampling signal Is, and the sampling voltage signal VS is converted into the metering value of the protection switch current signal Ip according to the sampling proportion parameter Q, so that the bit number of ADC needs to be high to ensure the full-range precision.

In other embodiments, the signal processing unit further comprises an arithmetic unit, a pre-precision sampling signal receiving port and a controller, wherein the arithmetic unit is used for receiving the current sampling signal Is and calculating the protection switch current signal Ip, the pre-precision sampling signal receiving port is used for receiving the first current loop parameter, the controller adjusts the high-precision sampling gain according to the first current loop parameter, and the high-precision sampling gain is output to the metering unit;
the controller is electrically connected to the arithmetic unit and the pre-precision sampling signal receiving port, respectively;
the metering unit is electrically connected to the signal conversion unit, and the signal conversion unit is electrically connected to the controller;
the signal conversion unit converts the protection switch current signal Ip into a sampling voltage signal Vs, and the metering unit receives the sampling voltage signal Vs and converts the sampling voltage signal Vs into a metering value according to the high-precision sampling gain.

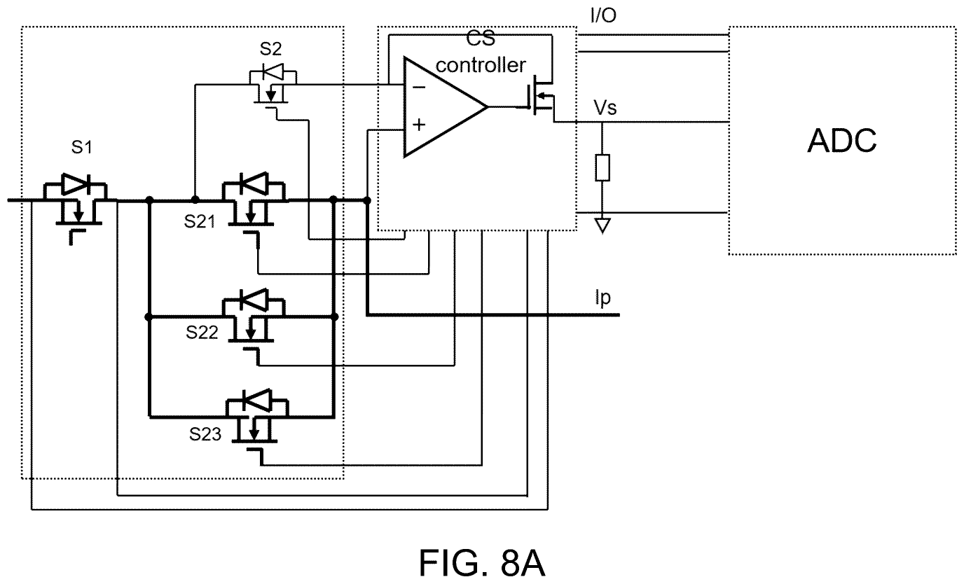

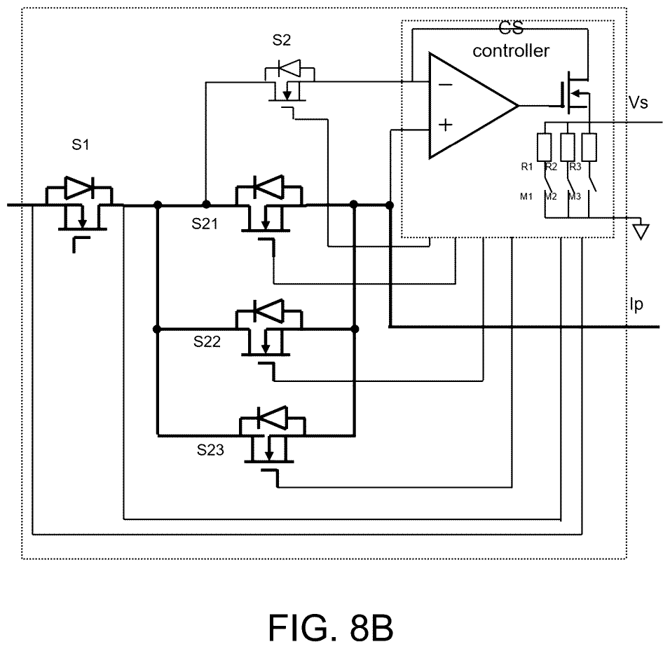

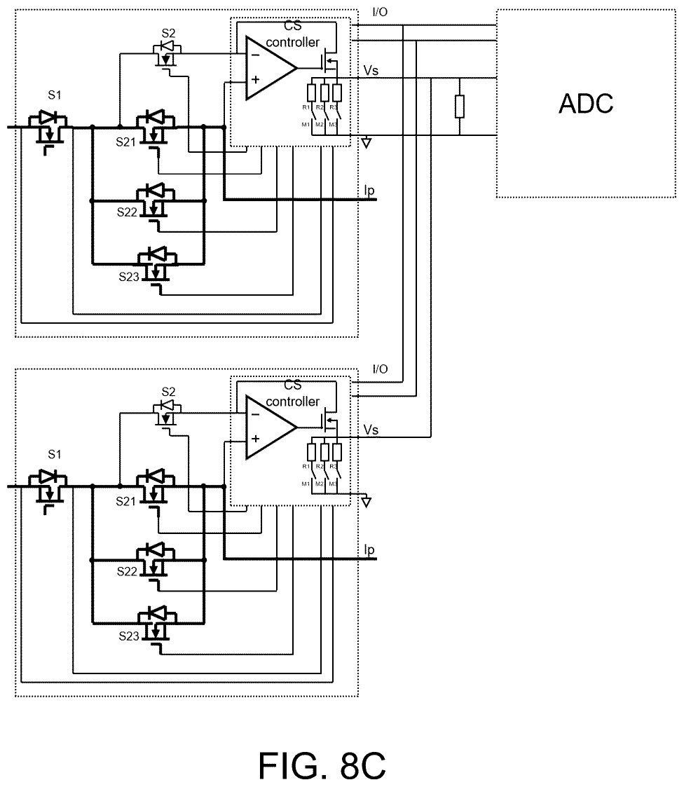

According to the embodiment, the K value switching state is transmitted to the metering unit through a digital signal such as an I/O port or an I2C, the K value is the reciprocal of the sampling proportion parameter Q, the K value of the sampling is recognized by the meter internal program to reduce the bit number of the ADC, as shown in FIG. 8A, the control signal is sent to the ADC through the I/O port according to the voltage drop control switches S21, S22 and S23 of the S1, and the current gain corresponding to the sampling circuit is identified, so that the sampling signal is converted into a linear sampling signal with the actual current.

Due to the fact that many signals need to be transmitted between the protection switch and the current sampling control unit, the PCB resources are wasted due to many interconnection, the sampling signals are prone to being interfered, and aiming at the problem, according to the embodiment, one silicon wafer is used for realizing integration of the sampling chip and the metering unit, as shown in FIG. 8B, the semiconductor process can be used for interconnection, and space occupation caused by interconnection is reduced.

In some other embodiments, as shown in FIG. 8C, after switching and sampling are performed on one IC wafer or part of different K stages in the package body, a plurality of such wafers or packages are connected in parallel for current expansion. For example, the first sampling chip and the second sampling chip are connected in parallel. After the parallel current report can be collected by the direct current source, a voltage is formed on the resistor and sent to the ADC for sampling. If M1 and M2 are of the same model, the sampling precision is 100 μA, the sampling precision is changed into 200 μA after parallel connection. According to the magnitude of the current, M1 and M2 can be switched, for example, the M1 with small current is turned-off, and is turned-on when the current is large. And the number of the switches with turning-on is reported for sampling, so that the equivalent sampling gain is digital corrected, and the high-precision sampling under the large current is still 100 μA.

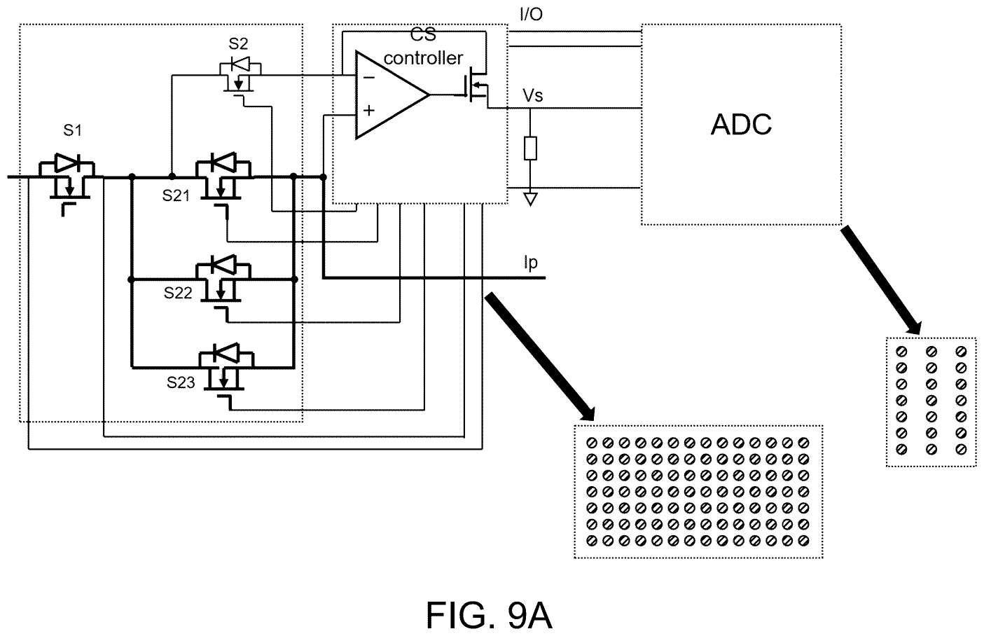

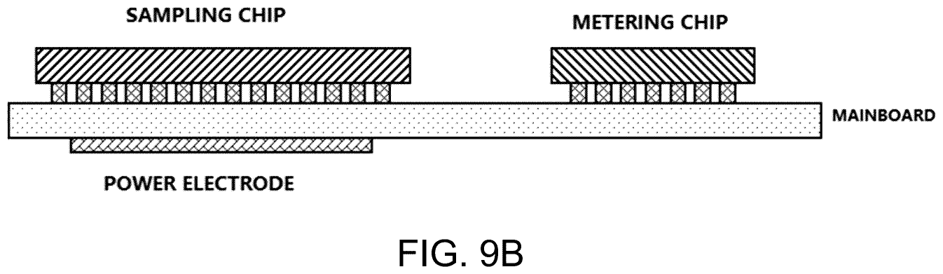

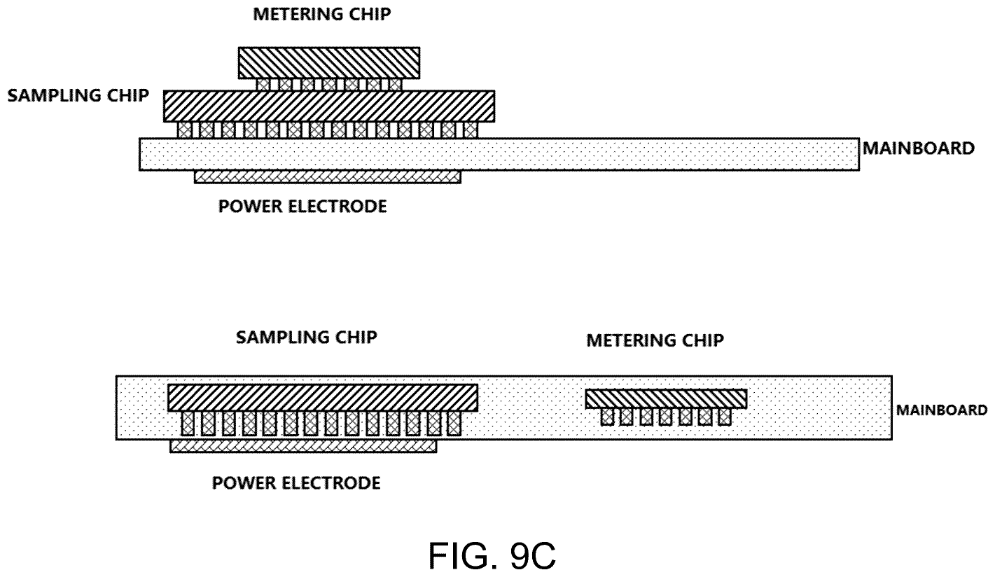

Due to the fact that the battery protection space is narrow, the packaging body left for the protection switch and the current sampling switch is limited, and the defect is that the number of pins of the packaging body is increased. According to the embodiment, a semiconductor packaging technology is used to manufacture a chip module. As shown in FIGS. 9A and 9B, the sampling chip and the pins of the metering unit output are led out through a semiconductor Bump process, high-precision welding is carried out on the upper surface of the BMS mainboard, a power electrode is arranged on the lower surface of the BMS mainboard, and the mainboard is electrically connected with the sampling chip, the metering unit and the power electrode.

In some other embodiments, as shown in FIG. 9C, the sampling chip can be embedded in the BMS mainboard through an embedded process, and the electrode is led out with high precision through a laser or etching punching technology. The metering unit can also be embedded together in the main board or arranged on the surface of the main board.

In conclusion, the bottleneck of current sampling is the amplification precision of high-precision operational amplifier. The core of the various embodiments disclosed by the application is characterized in that a high-precision operational amplifier is used for receiving current sampling signals with different amplification times but equivalent amplitudes so as to guarantee that the operational amplifier works in a good performance in each range. Taking the prior art as an example, when an independent current sampling signal is received, the current reporting precision is relatively stable in the range of 30%-100% of the load, and is better in the range of 20%-100% of the load, and is excellent in the range of 10%-100% of the load. That is, the MOS current capacity Rds(on) difference of each stage of switching is 3 times (30%), 5 times (20%) or even 10 times. As a detailed description, the Rds(on) of S22 is 3 times (30%), 5 times (20%) or even 10 times of the Rds(on) of S21, and the Rds(on) of S23 is 3 times (30%), 5 times (20%) or even 10 times of the Rds(on) of S22. In this way, it can be guaranteed that the current sampling signal of the input terminal of the operational amplifier is equivalent intensity after switching. For example, in the prior art, when the precision of 1 mA is achieved, the sampling resistance is 1 mOhm, that is, 1 μV precision. That is, the precision of operational amplifier is 1 μV. When the internal resistance of the MOS is 1 mOhm, 1 mA can be sampled; and when lower current is needed, the internal resistance of the MOS is cut to 10 mOhm, so that 1 μV/100 μA sampling can be realized.

Taking a mobile phone battery as an example, the current maximum current requirement is 24 A, the loss is as high as 0.576 W, the customer experience is influenced, the large-size resistor is needed, the BMS volume is influenced, and the battery capacity is sacrificed. If the precision is 100 μA, the resistance is 10 mOhm, and the loss is 5.76 W, which is completely unacceptable in a mobile phone occasion, and therefore, the 100 μA precision cannot be realized.

According to the embodiments disclosed by the application, the sampling resistor can be completely removed, and full-range high-precision sampling as low as 100 μA or even lower, as high as 24 A and even higher can be realized only by protecting the internal resistance switching of the MOS.

The above description of the disclosed embodiments enables a person skilled in the art to implement or use the present application. Various modifications to these embodiments will be readily apparent to those skilled in the art, and the generic principles defined herein may be implemented in other embodiments without departing from the spirit or scope of the application. Thus, the present application will not be limited to the embodiments shown herein but is to be accorded the widest scope consistent with the principles and novel features disclosed herein.

What is claimed is:

1. A high-precision current detection method for current detection in a current loop with at least one protection switch, comprising:
arranging sampling bridge arms which are connected in parallel on the at least one protection switch, wherein each of the sampling bridge arms comprises at least one current sampling switch and at least one signal processing unit which are connected in series; the number of the current sampling switches is at least two, and/or the corresponding protection switches are at least two connected in parallel; the at least one signal processing unit is configured to process a current sampling signal Is and configured to adjust the switching states of the current sampling switch and/or the protection switch;
obtaining a current sampling signal Is by using a mirror current source method performed by the current sampling switches;
presetting at least one sampling proportion parameter adjustment threshold;
sampling a first current loop parameter, the first current loop parameter being used for representing a high and low state of the load of a current loop;
determining a magnitude relationship between the first current loop parameter and the sampling proportional parameter adjustment threshold, and adjusting a switching state of the current sampling switch and/or the protection switch according to a determination result;
calculating a current signal Ip according to the current sampling signal Is, and calculating a protection switch current signal Ip by means of a formula (1.1) and a formula (1.2):
$$Q = {R}_{s} / {R}_{p} ; \qquad ( 1.1 )$$
$${I}_{p} = Q \cdot {I}_{s} ; \qquad ( 1.2 )$$
wherein Rₚ is a total equivalent resistance of the protection switch in on state, Rs is a total equivalent resistance of the current sampling switch in on state, and Q is the sampling proportion parameter.

2. The high-precision current detection method of claim 1, wherein
the sampling proportion parameter Q is stepped down along with the increase of the load of the current loop by adjusting the switching state of the current sampling switch and/or the protection switch.

3. The high-precision current detection method of claim 1, wherein
sampling bridge arms are respectively arranged on at least two parallel protection switches, and signal output ends of the sampling bridge arms are electrically connected with each other.

4. The high-precision current detection method of claim 1, wherein
sampling bridge arms are arranged on the at least two parallel protection switches, the sampling bridge arm comprises a current sampling switch corresponding to the protection switch and at least one signal processing unit, one end of the current sampling switch is electrically connected with one input end of the signal processing unit, and the at least two current sampling switches are electrically connected with the same signal processing unit.

5. The high-precision current detection method of claim 1, wherein the protection switch and the corresponding current sampling switch are integrated in the same chip.

6. A chip module using the high-precision current detection method of claim 1, comprising:
at least one protection switch, at least one current sampling switch, and at least one signal processing unit;
wherein the at least one current sampling switch is electrically connected to one input end of the at least one signal processing unit;
two ends of the at least one protection switch are respectively electrically connected to the other input end of the at least one signal processing unit and the at least one current sampling switch.

7. The chip module of claim 6, further comprising:
a metering unit, wherein the metering unit is configured to receive a voltage sampling signal Vs converted by a current sampling signal Is, and configured to convert the sampling voltage signal Vs into a metering value of a protection switch current signal Ip according to a sampling proportion parameter Q;
wherein the at least one signal processing unit comprises an arithmetic unit, a first current loop parameter transmission port, and a controller;
the arithmetic unit is configured to maintain the same voltage difference between the current sampling switch and the corresponding protection switch;
the first current loop parameter transmission port is configured to receive or output a first current loop parameter;
the controller is configured to adjust the turning-on and turning-off of the at least one current sampling switch and/or the at least one protection switch;
the controller is electrically connected to the arithmetic unit and the first current loop parameter transmission port, respectively;
the metering unit is electrically connected to the controller.

8. The chip module of claim 7, wherein
the metering unit is electrically connected with a first current loop parameter transmission port, and the first current loop parameter transmission port outputs a first current loop parameter to the metering unit;
the metering unit is configured to obtain a corresponding sampling proportion parameter Q according to the first current loop parameter, and configured to convert the sampling voltage signal Vs into a metering value for protecting the switching current signal Ip.

9. The chip module of claim 7, wherein
the signal processing unit further comprises an auxiliary switch unit, and the auxiliary switch unit is configured to adjust the decoupling resistance value according to the first current loop parameter, so that the product of the decoupling resistance value and the sampling proportion parameter Q corresponding to the first current loop parameter is a constant value;
the controller is electrically connected to the auxiliary switch unit;
the auxiliary switch unit is electrically connected to the metering unit;
the metering unit is configured to receive the voltage sampling signal Vs obtained by multiplying the current sampling signal Is and the decoupling resistance value.

10. The chip module of claim 9, further comprising:
at least one first protection switch which is not provided with a sampling bridge arm in parallel;
the first current loop parameter transmission port is electrically connected to two ends of the first protection switch, and the first current loop parameter transmission port is configured to receive a voltage difference between two ends of the first protection switch as a first current loop parameter.

11. The chip module of claim 9, wherein the current loop is a battery charging current loop;
wherein the first current loop parameter transmission port is electrically connected with the battery, and the first current loop parameter transmission port is configured to receive the battery voltage difference as a first current loop parameter.

12. The chip module of claim 10, wherein the first protection switch, the protection switch and the sampling bridge arm are correspondingly integrated in the same sampling chip.

13. The chip module of claim 12, wherein at least two sampling chips are arranged, at least two sampling chips are connected in parallel, and the metering unit is configured to receive a sampling voltage signal Vs of each sampling chip.

14. The chip module of claim 12, further comprising:
a mainboard, wherein the sampling chip is arranged on the upper surface of the mainboard or embedded in the mainboard, the metering unit is arranged on the upper surface of the mainboard or embedded in the mainboard, a power electrode is arranged on the lower surface of the mainboard, and the mainboard is electrically connected with the sampling chip, the metering unit and the power electrode.

15. A step type sampling current decoupling method, adapted to a chip module, wherein the chip module comprises:
a metering unit, wherein the metering unit is configured to receive a voltage sampling signal Vs obtained by multiplying a current sampling signal Is and a decoupling resistance value, and configured to convert the sampling voltage signal Vs into a metering value of a protection switch current signal Ip according to a sampling proportion parameter Q;
at least one signal processing unit, comprising:
a first current loop parameter transmission port, configured to receive or output a first current loop parameter,
an auxiliary switch unit, electrically connected to the metering unit, wherein the auxiliary switch unit is configured to adjust the decoupling resistance value according to the first current loop parameter, so that a product of the decoupling resistance value and the sampling proportion parameter Q corresponding to the first current loop parameter is a constant value; and
a controller electrically connected to the auxiliary switch unit,
wherein the step type sampling current decoupling method comprises:
S1, setting a corresponding number of auxiliary switch units according to the number n of protection switches, wherein the relationship between the protection switch and the auxiliary switch unit satisfies formula (2):
$${R}_{p 1} ( \frac{1}{{R}_{1}} + \frac{1}{{R}_{2}} + … + \frac{1}{\text{?}} ) \qquad ( 2 )$$
$$= ( {R}_{p 1} + {R}_{p 2} ) ( \frac{1}{{R}_{1}} + \frac{1}{{R}_{2}} + … + \frac{1}{\text{?}} )$$
$$⋮$$
$$= ( {R}_{p 1} + {R}_{p 2} + … + \text{?} ) ( \frac{1}{{R}_{1}} + \frac{1}{{R}_{2}} + … + \frac{1}{\text{?}} )$$
$$⋮$$
$$= ( {R}_{p 1} + {R}_{p 2} + … + \text{?} ) ( \frac{1}{{R}_{1}} + \frac{1}{{R}_{2}} )$$
$$= ( {R}_{p 1} + {R}_{p 2} + … + \text{?} ) ( \frac{1}{{R}_{1}} ) ;$$
$$\text{?} \text{indicates text missing or illegible when filed}$$
wherein Rp1, Rp2 . . . Rpn is total equivalent resistance of the first, the second, and the nth protection switches, R1, R2 . . . Rn is the sampling resistance values of the first, the second, and the nth auxiliary switch units, wherein j is an integer, and 1<j<n−1;
presetting (n−1) threshold values form the first threshold value to the (n−1)^{th} threshold value which are from small to large;
S2: acquiring the first current loop parameter, and determining a magnitude relationship between the first current loop parameter and the first threshold to the (n−1)^{th} threshold;
S3, if the first current loop parameter is lower than the first threshold, turning-on the first protection switch and all the auxiliary switch units;
if the first current loop parameter is higher than the (j−1)^{th} threshold value and is lower than the j^{th} threshold value, turning-on the first to the j^{th} protection switches and the first to (n−j+1)^{th} auxiliary switch units, wherein j is an integer, and 1<j<n−1;
if the first current loop parameter is higher than the (n−1)^{th} threshold, turning on all the protection switches and the first auxiliary switch unit;
S4: taking the total equivalent resistance of the turning-on auxiliary switch unit as a decoupling resistance value, and outputting the voltage value of the two ends of the auxiliary switch unit as a sampling voltage signal Vs.

16. A high-precision current detection unit for current detection in a current loop with at least one protection switch, comprising:
at least two protection switches in parallel, a current sampling switch, a signal processing unit;
wherein the first end of the current sampling switch is electrically connected with the first end of the protection switch;
the first input end of the signal processing unit is electrically connected with the second end of the current sampling switch;
the signal processing unit is configured to process a current sampling signal Is and configured to adjust the switching states of the current sampling switch and/or the protection switch;
a first current loop parameter is sampled by the high-precision current unit, the first current loop parameter is being used for representing a high and low state of the load of a current loop; the current sampling signal Is is used to obtain a current signal Ip by means of a formula:
$${I}_{p} = Q \cdot {I}_{s} ;$$
wherein Q is the sampling proportion parameter, and the sampling proportion parameter Q is a ratio of the total equivalent resistance of the conduction sampling switch and the total equivalent resistance of the conduction protection switch.

17. The high-precision current detection unit of claim 16, wherein the sampling proportion parameter Q is stepped down along with the increase of the load of the current loop by adjusting the switching state of the current sampling switch and/or the protection switch.

18. The high-precision current detection unit of claim 16, wherein the current sampling switch is configured to obtain a current sampling signal Is by using a mirror current source method.

19. The high-precision current detection unit of claim 16, wherein the signal processing unit is configured to:
preset at least one sampling proportion parameter adjustment threshold;
determine a magnitude relationship between the first current loop parameter and the sampling proportional parameter adjustment threshold; and
adjust a switching state of the current sampling switch and/or the protection switch according to a determination result.

20. The high-precision current detection unit of claim 16, wherein the protection switch and the corresponding current sampling switch are integrated in the same chip.

21. The high-precision current detection unit of claim 16, further comprising:
a first protection switch, wherein the first protection switch is connected with the protection switch in series in the current loop.

22. The high-precision current detection unit of claim 21, wherein the first protection switch, the protection switch and the corresponding current sampling switch are integrated in the same chip.

23. A high-precision current detection chip module, comprising:
a high-precision current detection unit in claim 16 and a metering unit, wherein the metering unit is configured to receive a voltage sampling signal Vs converted by a current sampling signal Is, and configured to convert the sampling voltage signal Vs into a metering value of a protection switch current signal Ip according to the sampling proportion parameter Q;
wherein the signal processing unit comprises an arithmetic unit, a first current loop parameter transmission port and a controller;
the arithmetic unit is configured to maintain the same voltage difference between the current sampling switch and the corresponding protection switch;
the first current loop parameter transmission port is configured to receive or output a first current loop parameter;
the controller is configured to adjust the turning-on and turning-off of the current sampling switch and/or the protection switch;
the controller is electrically connected to the arithmetic unit and the first current loop parameter transmission port respectively;
the metering unit is electrically connected to the controller.

24. The high-precision current detection chip module of claim 23, wherein the metering unit is electrically connected with a first current loop parameter transmission port, and the first current loop parameter transmission port outputs a first current loop parameter to a metering unit;
the metering unit is configured to obtain a corresponding sampling proportion parameter Q according to the first current loop parameter, and configured to convert the sampling voltage signal Vs into a metering value for protecting the switching current signal Ip.

25. The high-precision current detection chip module of claim 23, wherein the signal processing unit further comprises an auxiliary switch unit, and the auxiliary switch unit is configured to adjust a decoupling resistance value according to the first current loop parameter, so that the product of the decoupling resistance value and the sampling proportion parameter Q corresponding to the first current loop parameter is a constant value;
the controller is electrically connected to the auxiliary switch unit;
the auxiliary switch unit is electrically connected to the metering unit;
the metering unit is configured to receive a voltage sampling signal Vs obtained by multiplying the current sampling signal Is and the decoupling resistance value.

26. The high-precision current detection chip module of claim 25, wherein the current loop is a battery charging current loop;
wherein the first current loop parameter transmission port is electrically connected with the battery, and the first current loop parameter transmission port is configured to receive a battery voltage difference as a first current loop parameter.

27. The high-precision current detection chip module of claim 25, wherein the signal processing unit is configured to:
set a corresponding number of auxiliary switch units according to the number n of protection switches and (n−1) threshold values form the first threshold value to the (n−1)^{th} threshold value which are from small to large;
determine the number of the turning-on protection switches and the turning-on auxiliary switch units according to the first current loop parameter and the first threshold to the (n−1)^{th} threshold;
if the first current loop parameter is lower than the first threshold value, turn on the first protection switch and all the auxiliary switch units;
if the first current loop parameter is higher than the (n−1)^{th} threshold value, turn on all the protection switches and the first auxiliary switch unit.

28. The high-precision current detection chip module of claim 23, wherein the protection switch and the corresponding current sampling switch are integrated in the same chip;
wherein the high-precision current detection chip module further comprises a mainboard,
wherein the sampling chip is arranged on the upper surface of the mainboard or embedded in the mainboard, and the metering unit is arranged on the upper surface of the mainboard or embedded in the mainboard, a power electrode is arranged on the lower surface of the mainboard, and the mainboard is electrically connected with the sampling chip, the metering unit and the power electrode.

29. The high-precision current detection chip module of claim 23, further comprising:
a first protection switch, wherein the first protection switch is connected with the protection switch in series in the current loop; the first protection switch, the protection switch and the corresponding current sampling switch are integrated in the same chip;
a mainboard, wherein the sampling chip is arranged on the upper surface of the mainboard or embedded in the mainboard, and the metering unit is arranged on the upper surface of the mainboard or embedded in the mainboard, and the mainboard is electrically connected with the sampling chip, the metering unit and the power electrode.

30. The high-precision current detection chip module of claim 25, further comprising:
at least one first protection switch, wherein the at least one first protection switch is connected with the protection switch in series in the current loop;
wherein the first current loop parameter transmission port is electrically connected to two ends of the first protection switch, and the first current loop parameter transmission port is configured to receive a voltage difference between two ends of the first protection switch as a first current loop parameter.

31. A high-precision current detection integrated chip, comprising:
a protection switch and a current sampling switch;
wherein the first end of the current sampling switch is electrically connected with the first end of the protection switch;
the second end of the current sampling switch is electrically connected with a signal processing unit, and the current sampling switch is configured to obtain a current sampling signal Is by using a mirror current source method;
the signal processing unit is configured to process the current sampling signal Is and adjusting the switching states of the current sampling switch and/or the protection switch;
the number of the protection switch is one and the number of the current sampling switch is at least two, or, the number of the protection switch is at least two.

32. The high-precision current detection integrated chip of claim 31, further comprising:
a first protection switch, wherein the first protection switch is reversely connected with the first end of the protection switch in series.

33. The high-precision current detection integrated chip of claim 31, wherein the number of the current sampling switches is two;
wherein the second ends of the current sampling switches are respectively connected with the corresponding signal processing unit, or,
the second ends of the current sampling switches are connected with the same signal processing unit.

34. A high-precision current detection chip module for current sampling in a current loop with the protection switch, comprising:
a current sampling switch, a protection switch, a signal processing unit, and a metering unit,
wherein the signal processing unit is configured to process a current sampling signal Is and configured to adjust switching states of the current sampling switch and the protection switch,
wherein the metering unit is configured to receive a voltage sampling signal Vs converted by the current sampling signal Is, and configured to convert the sampling voltage signal Vs into a metering value of a protection switch current signal Ip according to a sampling proportion parameter Q;
wherein a relationship between the sampling proportion parameter Q and the current signal Ip of the protection switch is:
$$Q = {R}_{s} / {R}_{p} ; {I}_{p} = Q \cdot {I}_{s} ;$$
wherein _{Rp} is the total equivalent resistance of the protection switch in on state, Rs is the total equivalent resistance of the current sampling switch in on state;
wherein the signal processing unit comprises an arithmetic unit, a first current loop parameter transmission port and a controller;
the arithmetic unit is configured to maintain the same voltage difference between the current sampling switch and the corresponding protection switch;
the first current loop parameter transmission port is configured to receive or output a first current loop parameter;
the controller is configured to adjust the turning-on and turning-off of the current sampling switch and/or the protection switch;
the controller is electrically connected to the arithmetic unit and the first current loop parameter transmission port respectively;
the metering unit is electrically connected to the controller.

35. The high-precision current detection chip module of claim 34, wherein the metering unit is electrically connected with a first current loop parameter transmission port, and the first current loop parameter transmission port outputs a first current loop parameter to a metering unit;
the metering unit is configured to obtain a corresponding sampling proportion parameter Q according to the first current loop parameter, and configured to convert the sampling voltage signal Vs into a metering value for protecting the switching current signal Ip.

36. The high-precision current detection chip module of claim 34, wherein the signal processing unit further comprises an auxiliary switch unit, and the auxiliary switch unit is configured to adjust a decoupling resistance value according to the first current loop parameter, so that the product of the decoupling resistance value and the sampling proportion parameter Q corresponding to the first current loop parameter is a constant value;
the controller is electrically connected to the auxiliary switch unit;
the auxiliary switch unit is electrically connected to the metering unit;
the metering unit is configured to receive a voltage sampling signal Vs obtained by multiplying the current sampling signal Is and the decoupling resistance value.

37. The high-precision current detection chip module of claim 34, wherein the current loop is a battery charging current loop;
wherein the first current loop parameter transmission port is electrically connected with the battery, and the first current loop parameter transmission port is configured to receive the battery voltage difference as a first current loop parameter.

38. The high-precision current detection chip module of claim 34, wherein the signal processing unit is configured to:
set a corresponding number of auxiliary switch units according to the number n of protection switches and (n−1) threshold values form the first threshold value to the (n−1)^{th} threshold value which are from small to large;
determine the number of the turning-on protection switches and the turning-on auxiliary switch units according to the first current loop parameter and the first threshold to the (n−1)^{th} threshold;
if the first current loop parameter is lower than the first threshold value, turn on the first protection switch and all the auxiliary switch units;
if the first current loop parameter is higher than the (n−1)^{th} threshold value, turn on all the protection switches and the first auxiliary switch unit.

39. The high-precision current detection chip module of claim 34, further comprising:
at least one first protection switch, wherein the at least one first protection switch is connected with the protection switch in series in the current loop;
the first current loop parameter transmission port is electrically connected to two ends of the first protection switch, and the first current loop parameter transmission port is configured to receive a voltage difference between two ends of the first protection switch as a first current loop parameter.

40. The high-precision current detection chip module of claim 34, further comprising:
a mainboard, wherein the sampling chip is arranged on the upper surface of the mainboard or embedded in the mainboard, the metering unit is arranged on the upper surface of the mainboard or embedded in the mainboard, and the mainboard is electrically connected with the sampling chip, the metering unit and the power electrode.
